(19) United States
(12) Patent Application Publication
(10) Pub. No.: US 2008/0003787 A1
(43) Pub. Date: Jan. 3, 2008

(54) METHOD OF MANUFACTURING SEMICONDUCTOR DEVICE

(75) Inventor: Hae Chang Yang, Cheongju-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/617,628

(22) Filed: Dec. 28, 2006

(30) Foreign Application Priority Data
Jun. 28, 2006 (KR) 2006-58568

(51) Int. Cl. H01L 21/04

(52) U.S. Cl. 438/510

(57) ABSTRACT

A method of manufacturing a semiconductor device includes forming a trench having sidewalls on a semiconductor substrate, the sidewalls of the trench defining a side surface of the substrate. A first impurity implanting process is performed on the trench to define a first impurity region of the substrate, the first impurity region extending a first depth into the substrate from the side surface of the substrate. An oxide layer is formed on the trench, the oxide layer covering the side surface of the substrate. A second impurity implanting process is performed on the trench via the oxide layer to define a second impurity region of the substrate that extends a second depth into the substrate from the side surface of the substrate. The trench is filled to form an isolation structure therein to define an active region. The first impurity region extends further into the substrate than the second impurity region.

### CROSS-REFERENCES TO RELATED APPLICATIONS

The present application claims priority to Korean patent application number 10-2006-58568, filed on Jun. 28, 2006, which is incorporated by reference in its entirety.

### BACKGROUND OF THE INVENTION

The present invention relates to a method of manufacturing a semiconductor device, and more particularly, to a method of manufacturing a semiconductor device in which the concentration of boron (B) is increased to prevent a segregation peak from being generated.

FIG. 1A and FIG. 1B are cross-sectional views for illustrating a conventional method of manufacturing a semiconductor device.

Referring to FIG. 1A, a tunnel oxide layer 12 and a polysilicon layer 14 are sequentially formed on a semiconductor substrate 10. The polysilicon layer 14, the tunnel oxide layer 12 and the semiconductor substrate 10 are then etched to form a trench 16. An inclined ion implanting process is performed in the trench 16. At this time, boron (B) is utilized in the ion implanting process.

Referring to FIG. 1B, a side wall oxide layer (not shown) is formed in the trench 16 and a high density plasma (HDP) oxide layer is formed on the entire structure to fill the trench with the HDP oxide layer. Then, a polishing process is carried out to form an isolation structure 18.

However, if the isolation structure 18 is formed as described above, the boron (B) segregation is concentrated at section “A” to cause a peak. A transistor having such a concentration peak generates stress in a subsequent heat process and oxidation process, and so the transistor is more easily degraded. The degradation increases standby current, thereby lowering the quality of the device.

In order to prevent the generation of the concentration peak, the segregation of boron (B) should be minimized or the concentration of boron (B) should be increased after performing the ion implanting process. To minimize the segregation of boron (B), heat should be reduced; however, it is difficult to reduce the thermal budget. If the amount of boron (B) is increased in the ion implantation process, the concentration of boron (B) is increased. Also, the isolation structure is influenced, and so a side effect is a decrease in breakdown voltage.

FIG. 2 is a graph showing the variation of drain current at low gate voltages for transistors having a segregation peak.

The curve “a” shows the drain current with respect to the applied gate voltage for the transistor with the segregation peak, and the curve “b” shows the drain current with respect o the applied gate voltage after the stress is induced on the transistor having the segregation peak. From curve “a” and curve “b”, it can be seen that the current-voltage characteristics of the transistor with the stress is more degraded than it is for the transistor without the stress.

### SUMMARY OF THE INVENTION

An embodiment of the present invention provides a method of manufacturing a semiconductor device in which the concentration of boron (B) is adjusted to improve the segregation peak of a transistor.

The method of manufacturing a semiconductor device according to one embodiment of the present invention comprises the steps of; forming a trench on a semiconductor substrate and performing a first impurity implanting process in the trench; forming a side wall oxide layer and a buffer oxide layer in the trench; performing a second impurity implanting process in the trench; and forming an insulating layer on an entire structure to fill the trench with the insulating layer and then performing a polishing process to form an isolation structure, thereby fixing an active area and a field area.

In one embodiment, a method of manufacturing a semiconductor device includes forming a trench having sidewalls in a semiconductor substrate, the sidewalls of the trench defining a side surface of the substrate. A first impurity implanting process is performed on the trench to define a first impurity region in the semiconductor substrate, the first impurity region extending a first depth into the substrate from the side surface of the substrate. An oxide layer is formed over the trench, the oxide layer covering the side surface of the substrate. A second impurity implanting process is performed on the trench via the oxide layer to define a second impurity region in the semiconductor substrate that extends a second depth into the substrate from the side surface of the substrate. The trench is filled to form an isolation structure therein to define an active region. The first impurity region extends further into the substrate than the second impurity region.

In another embodiment, a method of manufacturing a semiconductor device includes forming a trench on a semiconductor substrate. Dopants are implanted into the trench to form a first impurity region in the semiconductor substrate, the first impurity region extending a first depth into the substrate from a sidewall of the trench. Dopants are implanted into the trench to form a second impurity region in the semiconductor substrate, the second impurity region extending a second depth into the substrate from the sidewall of the trench, the second depth being less than the first depth. The method further including forming a buffer layer on the trench prior to implanting the dopants to form the second impurity region.

### BRIEF DESCRIPTION OF THE DRAWINGS

The features and advantages of the present invention will become apparent from the following description of specific embodiments given in conjunction with the accompanying drawings, in which:

FIG. 1A and FIG. 1B are cross-sectional views for illustrating a conventional method of manufacturing a semiconductor device;

FIG. 2 is a graph showing the variation of drain current with gate voltage for transistors having a segregation peak;

FIG. 3A to FIG. 3C are cross-sectional views of a device for illustrating sequentially a method of manufacturing a semiconductor device according to one embodiment of the present invention; and

FIG. 4 is a conceptual view showing the diffusion direction of boron (B) when the processes for implanting the first impurity and the second impurity having the first Rp and the second Rp according to the present invention are carried out.

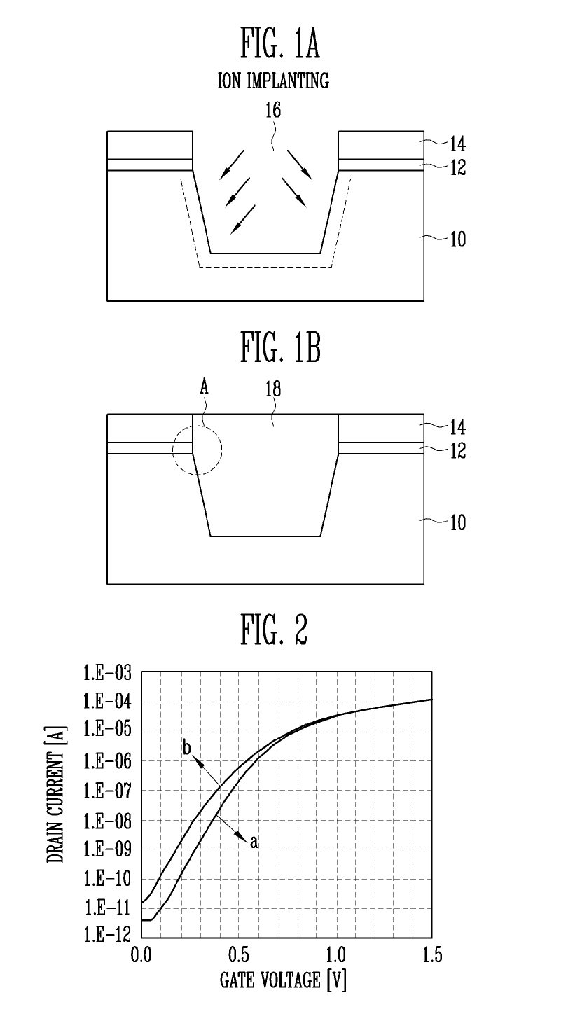

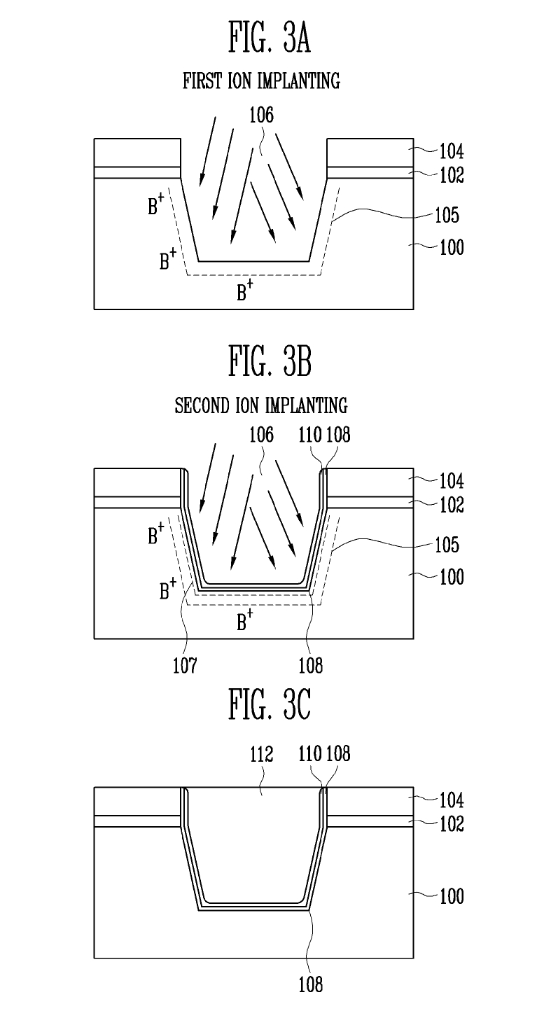

### DETAILED DESCRIPTION OF THE EMBODIMENT

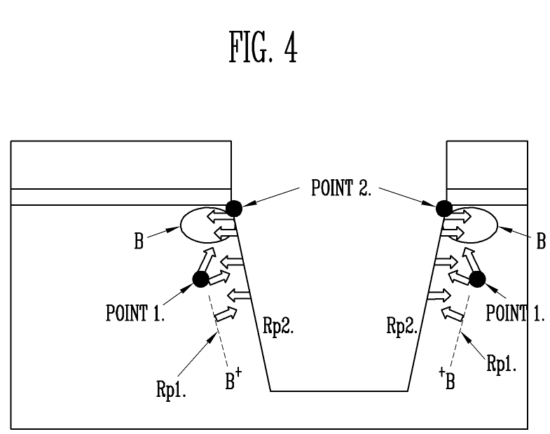

FIG. 3A to FIG. 3C are cross-sectional views of a device for illustrating sequentially a method of manufacturing a semiconductor device according to one embodiment of the present invention.

Referring to FIG. 3A, a tunnel oxide layer 102 (or tunnel dielectric layer) and a conductive layer 104 (e.g., polysilicon layer) for forming a gate electrode are sequentially formed on a semiconductor substrate 100. The conductive layer 104 for the gate electrode, the tunnel oxide layer 102 and the semiconductor substrate 100 are etched to form a trench 106. A first impurity implanting process is performed on the trench 106. The first impurity implanting process utilizes boron (B) and is performed turning for several directions (e.g., four directions) using energies of 10 KeV to 20 KeV and a dose of 1.0E11 to 9.0E11 atoms/cm². The first impurities (or dopants) are implanted at an inclination angle of 13° to 17°, preferably 15°. By performing the first impurity implanting process, a first impurity region 105 extends about 150 Å to 250 Å into the substrate from the sidewalls and the bottom of trench 106.

Referring to FIG. 3B, a side wall oxide layer 108 and a buffer oxide layer 110 are formed in the trench 106. The buffer oxide layer 110 is formed on the sidewall oxide layer 108 and has a thickness of 150 Å to 250 Å. A second impurity implanting process is then carried out for the trench 106. The second impurity implanting process utilizes boron (B) and is performed turning for several directions (e.g., four directions) using energies of 10 KeV to 20 KeV and a dose of 1.0E11 to 9.0E11 atoms/cm². The second impurities (or dopants) are implanted at an inclination angle of 13° to 17°, preferably 15°. By performing the second impurity implanting process, a second impurity region 107 is formed on the surface of the semiconductor substrate 100 which makes up the side wall and bottom area of the trench 106. The second impurity region 107 extends about 0 Å to 50 Å into the substrate from the edge of the substrate 100.

Referring to FIG. 3C, an insulating layer is formed on the entire structure to fill the trench 106. A polishing process is performed to form an isolation structure 112. The insulating layer is formed of oxide, e.g., a high density plasma (HDP) layer. An active area and a field area are defined by forming the isolation structure 112.

FIG. 4 is a conceptional view showing the diffusion direction of boron (B) when the processes for implanting the first impurity and the second impurity having the first Rp (projection of range) and the second Rp according to the present invention are carried out.

Referring to FIG. 4, once the process for implanting the first impurity is having the first Rp is carried out, boron (B) placed on point 1 (the first Rp) is diffused to a region B where a channel and an edge of an active are defined. When the process for implanting the second impurity having the second Rp is carried out, boron (B) placed on point 2 (the second Rp) is diffused to the region B. Due to the above phenomenon, the dosage of boron (B) ion is maintained as it is and a concentration of boron (B) in the region B is increased to improve the segregation peak.

Embodiments of the present invention as described above have one or more the following advantages:

First, by carrying out the processes for implanting the first impurity having the first Rp and the second impurity having the second Rp for the trench, it is possible to compensate for the decrease in concentration of boron (B) in the area where the channel and an edge of the active region meet.

Second, a segregation peak in the transistor can be improved by compensating for the decrease in concentration of boron (B) in the substrate at the substrate/tunnel oxide interface.

Third, a reliability of the device can be enhanced by improving the segregation peak so that the yield and quality of the device can be enhanced. Although the present invention has been described in connection with the specific embodiments, the scope of the present invention is not limited by the specific embodiments but should be interpreted by the appended claims. Further, it should be understood by those skilled in the art that various changes and modifications can be made without departing from the spirit and scope of the present invention.

What is claimed is:

1. A method of manufacturing a semiconductor device, the method comprising:
forming a trench having sidewalls in a semiconductor substrate, the sidewalls of the trench defining a side surface of the substrate;
performing a first impurity implanting process on the trench to define a first impurity region in the semiconductor substrate, the first impurity region extending a first depth into the substrate from the side surface of the substrate;
forming an oxide layer over the trench, the oxide layer covering the side surface of the substrate;
performing a second impurity implanting process on the trench via the oxide layer to define a second impurity region in the semiconductor substrate, the second impurity region extending a second depth into the substrate from the side surface of the substrate; and
filling the trench to form an isolation structure therein to define an active region.

2. The method of claim 1, wherein the first impurity region extends further into the substrate than the second impurity region.

3. The method of claim 1, wherein the oxide layer includes a sidewall oxide layer and a buffer oxide layer.

4. The method of claim 1, wherein the first and second impurity implanting processes utilize boron (B) and involve implanting the boron at an inclined angle.

5. The method of claim 1, wherein the first impurity implanting process is performed turning for several directions using an implantation energy of 10 KeV to 20 KeV and implanted at an inclination angle of 13° to 17°.

6. The method of claim 5, wherein the first impurity region is doped to a dopant concentration of 1.0E11 to 9.0E11 ions/cm².

7. The method of claim 5, wherein the second impurity implanting process is performed turning for several directions using an implantation energy of 10 KeV to 20 KeV and implanted at an inclination angle of 13° to 17°.

8. The method of claim 7, wherein the second impurity region is doped to a dopant concentration of 1.0E11 to 9.0E11 ions/cm².

9. The method of claim 1, wherein the first impurity region extends 150 Å to 250 Å into the substrate from the side surface of the substrate after the first impurity implanting process.

10. The method of claim 4, wherein dopants implanted in the first and second impurity regions diffuse to a channel and an edge of the active region.

11. The method of claim 1, wherein the second impurity region formed proximate to the side a surface of the substrate.

12. The method of claim 6, wherein the second impurity region configured to provide dopants that diffuse to a channel and an edge of the active region.

13. A method of manufacturing a semiconductor device, the method comprising:
forming a trench on a semiconductor substrate;
implanting dopants into the trench to form a first impurity region in the semiconductor substrate, the first impurity region extending a first depth into the substrate from a sidewall of the trench; and
implanting dopants into the trench to form a second impurity region in the semiconductor substrate, the second impurity region extending a second depth into the substrate from the sidewall of the trench, the second depth being less than the first depth.

14. The method of claim 13, further comprising:
forming a buffer layer on the trench prior to implanting the dopants to form the second impurity region.

15. The method of claim 14, wherein the buffer layer includes an oxide layer.

16. The method of claim 13, wherein the first and second impurity regions are formed by implanting the dopants at an inclined angle, the dopants used for forming the first impurity region includes boron (B).

17. The method of claim 13, wherein the dopants are implanted using an energy of no more than 20 KeV to form the first impurity region.

18. The method of claim 17, further comprising:
forming a buffer layer on the trench prior to implanting the dopants to form the second impurity region,
wherein the dopants are implanted using an energy of no more than 20 KeV to form the second impurity region.

19. The method of claim 13, wherein the first impurity region has a dopant concentration of 1.0E11 to 9.0E11 ions/cm².

20. The method of claim 13, wherein the first depth of the first impurity region is between 150 Å to 250 Å.
